(19) United States
(12) Patent Application Publication
(10) Pub. No.: US 2026/0266268 A1
(43) Pub. Date: Sep. 10, 2026

(54) SELF-CONTAINED BLOCKCHAIN MINING SYSTEMS, HIGH-ENERGY-DENSITY COMPUTING SYSTEMS, AND METHODS OF USE

(71) Applicant: OCEANBIT INC., Kailua, HI (US)

(72) Inventor: Nathaniel HARMON, Kailua, HI (US)

(73) Assignee: OCEANBIT INC., Kailua, HI (US)

(21) Appl. No.: 19/471,472

(22) PCT Filed: Apr. 3, 2024
(86) PCT No.: PCT/US2024/022869

§ 371 Date: Oct. 1, 2025

Related U.S. Application Data
(60) Provisional application No. 63/456,765, filed on Apr. 3, 2023.

(51) Int. Cl. F03G 7/05; F01D 15/00; G06F 1/20; H05K 7/20

(52) U.S. Cl. CPC F03G 7/05; F01D 15/00; G06F 1/20; H05K 7/20263; H05K 7/2079

(57) ABSTRACT

Self-contained blockchain mining and high-energy-density computing systems have a low temperature heat engine (LTHE) with a working fluid loop extended between a heat source and a heat sink; a blockchain mining device connected to receive electricity generated from the LTHE; a heat exchanger on the working fluid loop; and a coolant loop extended between the blockchain mining device and the working fluid loop (heat exchanger). A self-contained high-energy-density computing data center (HEDC) system is disclosed comprising: a low temperature heat engine (LTHE) with a working fluid loop extended between a heat source and a heat sink; an HEDC device connected to receive electricity generated from the LTHE; a heat exchanger on the working fluid loop; and a coolant loop extended between the HEDC device and the working fluid loop (heat exchanger). A method is also disclosed comprising: generating electricity using a low temperature heat engine (LTHE); operating an HEDC device, using electricity generated by the LTHE, to carry put computer processes; and cooling the HEDC device by heat exchange with working fluid of the LTHE.

This application is the 371 National Stage Filing for PCT Application PCT/US24/22869, filed on Apr. 3, 2024, which claims priority to U.S. Provisional Application 63/456,765, both of which are fully incorporated herein by reference.

### TECHNICAL FIELD

This document relates to self-contained high-energy-density computing systems, blockchain mining systems, and related methods of use.

### BACKGROUND

The following paragraphs are not an admission that anything discussed in them is prior art or part of the knowledge of persons skilled in the art.

Traditional data centers typically focus on providing scalable computing resources, storage, and networking services to support a variety of general-purpose, multi-tenant applications and workloads, prioritizing reliability, flexibility, scalability, availability, ease of use, and security. High Energy Density Computing (HEDC) data centers are purpose-built and optimized for computationally intensive tasks such as blockchain mining, high-performance computing (HPC), supercomputing, large language model (LLM) training, machine learning (ML), artificial intelligence (AI), neural networks, and global climate modeling. HEDC systems prioritize raw compute power utilizing specialized hardware configurations of high-performance Graphics Processing Units (GPU), Tensor Processing Units (TPU), Central Processing Units (CPU), Field Programmable Gate Arrays (FPGA), and Application Specific Integrated Circuits (ASIC) optimized to accelerate the HEDC's specific computational task to the detriment of general-purpose computing. HEDC systems require extensive energy and cooling technologies to successfully operate. In many HEDC applications, like blockchain mining, the systems are uneconomical to operate, as the cost for power is close to or greater than the potential revenue earned from the computing activities. Bitcoin is the most famous blockchain system in existence and is an example of a decentralized digital currency that operates independently of central banks and uses cryptography (authenticated via mining processes) to secure and verify transactions on a public ledger called the blockchain. Bitcoin requires significant amounts of energy to operate, as its mining process involves solving complex mathematical problems that require extensive computing power.

Ocean Thermal Energy Conversion (OTEC) is a renewable energy technology that harnesses the temperature difference in ocean water to generate electricity. OTEC has the potential to provide a significant source of clean and sustainable. However, previous OTEC projects have failed to provide scalable, reliable, and cost-effective power solutions, and have not been generally adopted around the world.

### SUMMARY

A self-contained high-energy-density computing data center (HEDC) system is disclosed comprising: a low temperature heat engine (LTHE) with a working fluid loop extended between a heat source and a heat sink; an HEDC device connected to receive electricity generated from the LTHE; a heat exchanger on the working fluid loop; and a coolant loop extended between the HEDC device and the working fluid loop (heat exchanger).

A method is also disclosed comprising: generating electricity using a low temperature heat engine (LTHE); operating an HEDC device, using electricity generated by the LTHE, to carry out computer processes; and cooling the HEDC device by heat exchange with working fluid of the LTHE.

A self-contained high-energy-density computing system is also disclosed comprising: a low temperature heat engine (LTHE) with a working fluid loop extended between a heat source and a heat sink; a data center connected to receive electricity generated from the LTHE; a heat exchanger on the working fluid loop; and a coolant loop extended between the data center and the heat exchanger.

A method is also disclosed comprising: generating electricity using a low temperature heat engine (LTHE); operating a high-energy-density computing (HEDC) device, using electricity generated by the LTHE, to carry out data center processes; and cooling the HEDC device by heat exchange with working fluid of the LTHE.

Embodiments of the present disclosure relate to the field of energy conversion and computation, and specifically to low temperature heat engines and high energy density computing. More particularly, some embodiments pertain to a system that improves the efficiency of a low temperature heat engine by reintegrating heat generated from high energy density computing, which is powered by the heat engine. In some cases, the disclosure combines two technologies, a low temperature heat engine and high energy density computing, to create a synergistic system that maximizes energy efficiency and reduces waste. The system may use the waste heat generated by the high energy density computing as a source of heat within a low temperature heat engine, creating a singular closed loop system that improves the overall efficiency of both technologies. The disclosure provides a solution to the challenge of effectively utilizing waste heat from high energy density computing in low temperature heat engines and contributes to the field of energy conversion by creating a more sustainable and efficient energy system.

In some cases, a method is disclosed for extracting electrical power from a low initial temperature heat source by means of a Low Temperature Heat Engine (LTHE) to power a High Energy Density Computing data center (HEDC), where the waste heat generated by the HEDC subsystem is transferred back into the LTHE subsystem by means of a heat transfer medium and a heat exchange power plant. The use of a coupled HEDC-LTHE as described may result in an efficient and cost-effective cooling solution for HEDC systems, compared to conventional cooling methods, and increases the efficiency while decreasing the costs of a LTHE.

In some cases, the embodiments disclosed provide one or more of: a fully integrated design, single system; computing devices that are part of a heat engine; improved Low Temp Heat Engine devices; a ship based HEDC system; a method of operating while grazing (i.e. moving) a ship in a body of water, such as the ocean; Ocean Thermal Energy Conversion processes; a power generation and data processing system that is not connected to land or does not have to be connected to land in all cases; a low latency/small bandwidth data connection; a satellite-operated system; modular design; a containerized HEDC system; immersion cooled technology for HEDC systems; an equatorial focused OTEC system; the ability to convert used or pre-existing ships to carry out such processes; a remote-operated system; a system for use in deep water; a system that performs internal calculations rather than cloud calculations; a system that incorporates Bitcoin mining, high-performance computing (HPC), supercomputing, large language model (LLM) training, machine learning (ML), artificial intelligence (AI), and/or neural network specialized hardware configurations of high-performance Graphics Processing Units (GPU), Tensor Processing Units (TPU), Central Processing Units (CPU), Field Programmable Gate Arrays (FPGA), and Application Specific Integrated Circuits (ASIC) information technology (IT) equipment optimized to accelerate the HEDC's specific computational task; a marriage of Bitcoin mining, high-performance computing (HPC), supercomputing, large language model (LLM) training, machine learning (ML), artificial intelligence (AI), and/or neural network and OTEC technologies; and methods of decarbonizing Bitcoin, high-performance computing (HPC), supercomputing, large language model (LLM) training, machine learning (ML), artificial intelligence (AI), and/or neural network.

In various embodiments, there may be included any one or more of the following features: the HEDC comprises a task-specialized configuration of processors comprising one or more of: high-performance Graphics Processing Units (GPUs), Tensor Processing Units (TPUs), Field Programmable Gate Arrays (FPGAs), and Application Specific Integrated Circuits (ASICs), arranged and interconnected to optimize performance for specific computational tasks. The HEDC comprises a blockchain mining device. The HEDC is configured to carry out one or more of the following operations: artificial intelligence, machine learning, large language models, generative AI, Neural Network, and supercomputing. The LTHE comprises a turbomachine connected to generate electricity for the HEDC device. The heat exchanger is on the working fluid loop upstream of the turbomachine. The turbomachine comprises a plurality of turbomachines. The plurality of turbomachines comprises: a first turbomachine downstream of the heat source but upstream of the heat exchanger; and a second turbomachine downstream of the heat exchanger but upstream of the heat sink. A heat source heat exchanger is between the heat source and the working fluid loop; and the working fluid loop is structured to cycle working fluid, in series, from the heat source heat exchanger, into the first turbomachine, back into the heat source heat exchanger, and into the second turbomachine. The system has a gas-liquid separator on the working fluid loop downstream of the heat source and upstream of the turbomachine, and structured to separate the working fluid into: a gasified stream that is supplied to the turbomachine; and a liquefied stream that is supplied to the heat exchanger and then to the turbomachine. The heat exchanger and the coolant loop are structured to superheat working fluid in the working fluid loop. A controller is configured to operate the LTHE and coolant loop to maintain a processor of the HEDC device within a safe operating range of temperature. The working fluid comprises ammonia. One or more circulation pumps are on the coolant loop or working fluid loop. A heat source heat exchanger is between the heat source and the working fluid loop; and a heat sink heat exchanger is between the heat sink and the working fluid loop. The heat exchanger is connected downstream of the heat source heat exchanger. The LTHE carries out an ocean thermal energy conversion (OTEC) process. The system forms a facility that collocates the HEDC device and the LTHE. The facility forms a boat. The HEDC device comprises a plurality of processors connected to a network interface; the network interface is connected to receive and transmit data through the internet. The HEDC comprises a blockchain mining device; the network interface is connected to a peer-to-peer network that stores or has access to a blockchain database, which is a distributed database stored on plural nodes in the peer-to-peer network, and stores transactional information for a digital currency; and the processors are connected to the network interface and adapted to mine transactions associated with the blockchain database and to communicate with the blockchain database. Operating the HEDC device using electricity generated from the LTHE. Generating electricity comprises cycling working fluid around a working fluid loop of the LTHE between a heat source, a turbomachine, and a heat sink. Cooling comprises cycling coolant around a coolant loop between the HEDC device and a heat exchanger, which is on the working fluid loop upstream of the turbomachine. The turbomachine comprises a first turbomachine and a second turbomachine; and the working fluid is cycled between: the first turbomachine downstream of the heat source but upstream of the heat exchanger; and the second turbomachine downstream of the heat exchanger but upstream of the heat sink. The working fluid loop is cycled in series, from a heat source heat exchanger, into the first turbomachine, back into the heat source heat exchanger, and into the second turbomachine. Cycling the working fluid comprises: cycling the working fluid from the heat source into a gas-liquid separator on the working fluid loop downstream of the heat source and upstream of the turbomachine; and separating the working fluid, using the gas-liquid separator into: a gasified stream that is supplied to the turbomachine; and a liquefied stream that is supplied to the heat exchanger and then to the turbomachine. Heat exchange with the working fluid superheats working fluid in the working fluid loop. Cooling comprises maintaining a processor of the HEDC device within a safe operating range of temperature. The LTHE carries out an ocean thermal energy conversion (OTEC) process. The method is carried out on a boat floating in the ocean. The working fluid loop comprises working fluid selected to alternate between liquid and gaseous phases during a loop cycle. The working fluid loop is structured to cycle working fluid, in series, from the heat source heat exchanger, into the first turbomachine, and into the heat exchanger. The safe operating range of temperatures is at or above the boiling point of the working fluid. The heat source comprises relatively cool ocean water, and the heat sink comprises relatively warm ocean water. The OTEC plant is structured to operate to generate electricity while moving along the surface of the ocean. Adjusting the input power of the HEDC device to balance other loads powered by the LTHE.

The foregoing summary is not intended to summarize each potential embodiment or every aspect of the subject matter of the present disclosure. These and other aspects of the device and method are set out in the claims.

### BRIEF DESCRIPTION OF THE FIGURES

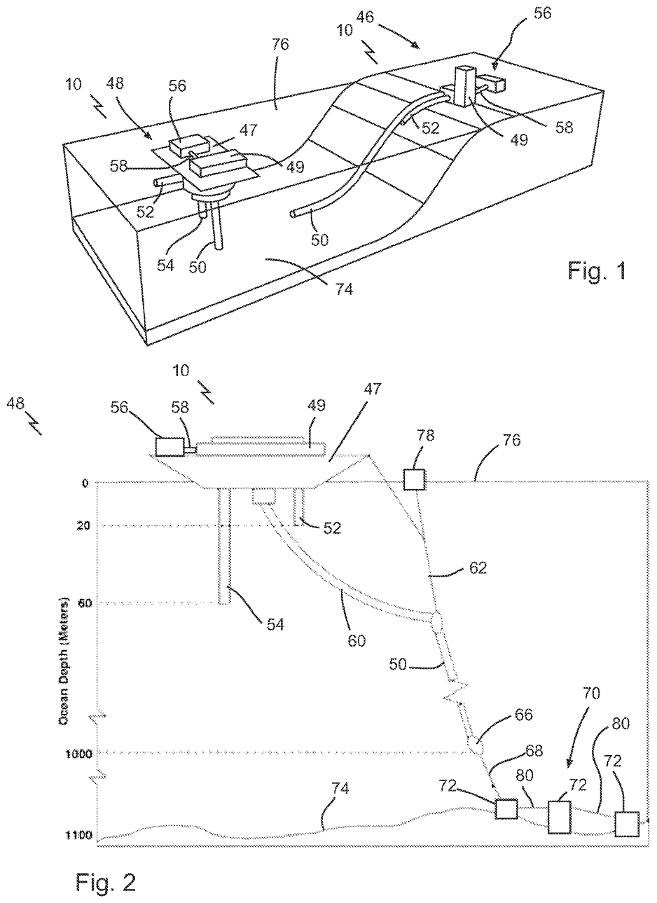

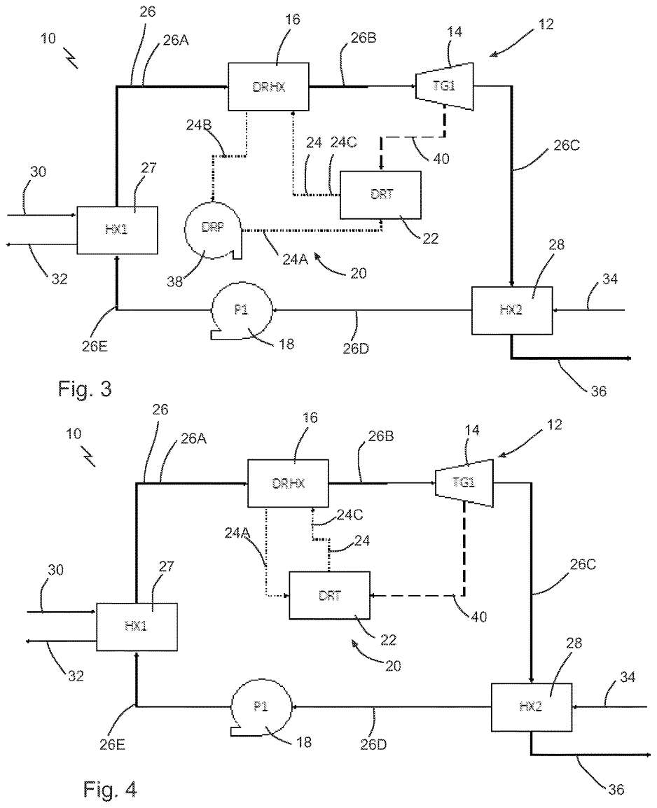

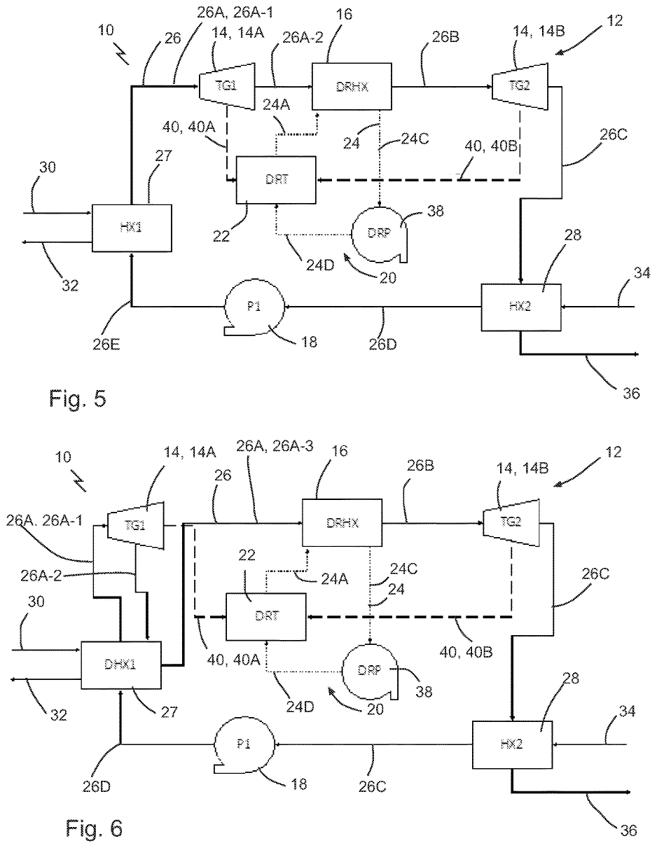

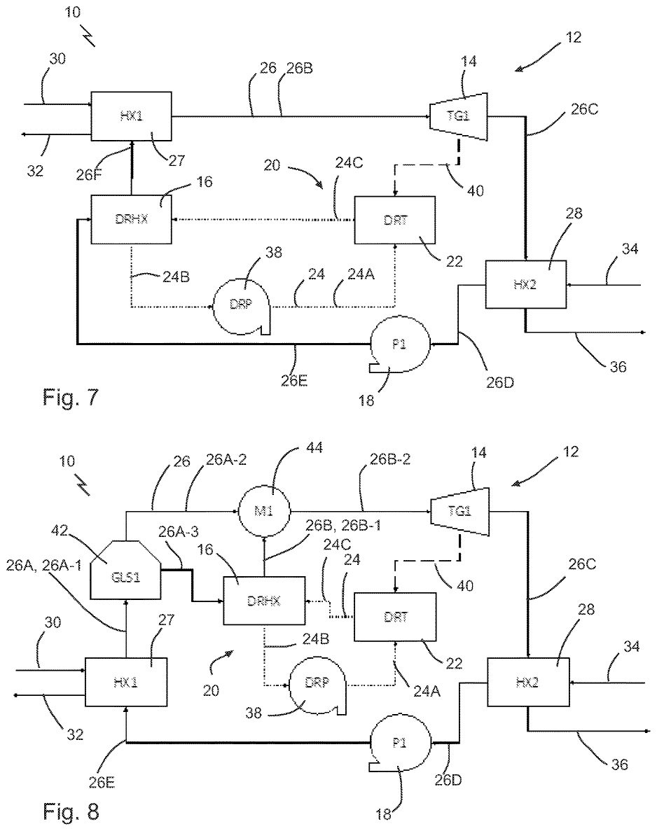

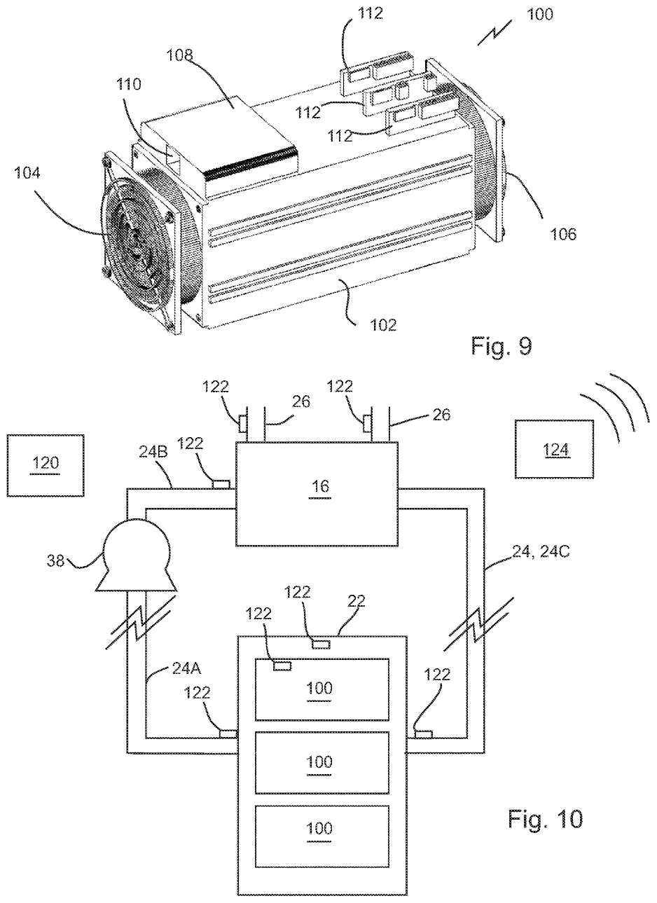

Embodiments will now be described with reference to the figures, in which like reference characters denote like elements, by way of example, and in which: FIG. 1 is a perspective view of both an onshore ocean thermal energy conversion (OTEC) and High Energy Density Computing (HEDC) facility and an offshore OTEC and HEDC facility. FIG. 2 is a side elevation, partial perspective, view of an offshore OTEC and HEDC facility, with a graph of ocean depth overlaid on the view for reference. FIG. 3 is a schematic diagram depicting a system comprising a low temperature heat engine (LTHE) where a single stream or dual streams of working fluid is/are superheated using waste heat transferred from the cooling of a high energy density computing (HEDC) data center operation, by means of a heat exchange and a single turbine system also providing power to the HEDC operation. FIG. 4 is a schematic diagram depicting a variation of the system of FIG. 1, wherein a heat transfer medium employed by the HEDC data center allows for the removal of the coolant pump in FIG. 1. FIG. 5 is a schematic diagram depicting an embodiment of a system comprising an LTHE where a single stream or dual streams of working fluid is/are reheated by waste heat transferred from the HEDC data center operation by means of a heat exchange power plant and a dual turbine system providing power to the HEDC data center operation. FIG. 6 is a schematic diagram depicting a variation of the system of FIG. 5, where a single stream or dual streams of working fluid is/are reheated by a dual flow heat exchanger in a regenerative Rankine cycle, then superheated by waste heat transferred from the HEDC operation by means of a heat exchange apparatus and a dual turbine system providing power to the HEDC operation. FIG. 7 depicts an embodiment of a system comprising an LTHE where a single stream or dual streams of working fluid is/are preheated by waste heat transferred from the HEDC data center operation by means of a heat exchange power plant and a single turbine system providing power to the HEDC data center operation. FIG. 8 depicts an embodiment of a system comprising an LTHE where a single stream or dual streams of working fluid is/are partially evaporated where the gas and liquid components are split by means of a gas liquid separator apparatus, and the liquid stream is fully vaporized by the waste heat transferred from the HEDC operation by means of a heat exchange apparatus and a single turbine system providing power to the HEDC operation. FIG. 9 is a perspective view of an example of an HEDC device, a blockchain mining processor, in the exemplary form of an application specific integrated circuit (ASIC) processor for Bitcoin mining. FIG. 10 is a schematic of a coolant loop, heat exchanger, and HEDC device, connected for heat exchange with a working fluid loop of an LTHE.

### DETAILED DESCRIPTION

Immaterial modifications may be made to the embodiments described here without departing from what is covered by the claims.

In thermodynamics and engineering, a heat engine is a system that converts heat to usable energy, particularly mechanical energy, which can then be used to do mechanical work. While originally conceived in the context of mechanical energy, the concept of the heat engine has been applied to various other kinds of energy, particularly electrical, since at least the late 19th century. The heat engine does this by bringing a working fluid from a higher state temperature to a lower state temperature—in some cases transitioning a fluid between phases. A heat source generates thermal energy that brings the working substance to the higher temperature state. The working substance generates work in the working body of the engine while transferring heat to the colder sink until it reaches a lower temperature state. During this process some of the thermal energy is converted into work by exploiting the properties of the working substance. The working substance can be any system with a non-zero heat capacity, but it usually is a gas or liquid. During this process, some heat is normally lost to the surroundings and is not converted to work. Also, some energy is unusable because of friction and drag.

In general, an engine is any machine that converts energy to mechanical work, and a heat engine is no different. Heat engines distinguish themselves from other types of engines by the fact that their efficiency is fundamentally limited by Carnot's theorem. Although this efficiency limitation can be a drawback, an advantage of heat engines is that most forms of energy can be easily converted to heat by processes like exothermic reactions (such as combustion), nuclear fission, absorption of light or energetic particles, friction, dissipation and resistance. Since the heat source that supplies thermal energy to the engine can thus be powered by virtually any kind of energy, heat engines cover a wide range of applications. Heat engines are often confused with the cycles they attempt to implement. Typically, the term “engine” is used for a physical device and “cycle” for the models.

A heat engine may carry out a Rankine cycle, which is an idealized thermodynamic cycle describing the process by which certain heat engines, such as steam turbines or reciprocating steam engines, allow mechanical work to be extracted from a fluid as it moves between a heat source and heat sink. Heat energy is supplied to the system, in many cases via a boiler, where the working fluid (typically water) is converted to a high-pressure gaseous state (such as steam) in order to turn a turbine. After passing over the turbine the fluid is allowed to condense back into a liquid state as waste heat energy is rejected before being returned to boiler, completing the cycle. Friction losses throughout the system are often neglected for the purpose of simplifying calculations as such losses are usually much less significant than thermodynamic losses, especially in larger systems.

Low temperature heat engines (LTHE) have gained increasing attention as a promising technology for harnessing low-grade heat sources and converting them into useful energy. An LTHE includes one that operates below 100 degrees Celsius (boiling point of water). In an OTEC context the LTHE may operate at or below 30 degrees Celsius. They are designed to operate at temperatures significantly lower than conventional heat engines and are more efficient and cost-effective in utilizing low-grade heat sources such as renewable energy and waste heat.

Despite the advantages of low temperature heat engines, their efficiency is often limited by the low temperature of the heat source and the low conversion efficiency of the heat engine itself. The low temperature of the heat source means that there is less energy available to be converted into useful work, which in turn results in a lower conversion efficiency. Additionally, low temperature heat engines may also face technical challenges such as corrosion, scaling, and materials degradation, which can further reduce their efficiency. To overcome these challenges and improve the efficiency of low temperature heat engines, there is a need for a system that effectively harnesses low-grade heat sources and converts them into useful energy. An additional factor resulting in further reductions in the overall thermodynamic efficiency of a low temperature heat engine is the loss associated with providing necessary controls on the turbine for precise frequency regulation required for exporting power to an electrical grid. This introduces pressure losses in the turbine cycle that further limit the work that can be extracted from the system.

High energy density computing, on the other hand, requires a significant amount of energy to power the computers and generates heat as a byproduct. This waste heat is typically treated as a burden due to the cost of the cooling systems required to remove it from the computer systems to prevent overheating. However, this waste heat can also be valuable if effectively utilized. An HEDC system may be referred to as a type of data center, which is an example of a computing system, usually contained in a building, a dedicated space within a building, a group of buildings, or in modular containers. A traditional data center may be used to house computer systems and associated components, such as telecommunications and storage systems typically focused on providing scalable general purpose computing resources, storage, and networking services to support a variety of general-purpose, multi-tenant applications and workloads prioritizing reliability, flexibility, scalability, availability, ease of use, and security. Whereas HEDC data centers are purpose-built and optimized for computationally intensive tasks such as blockchain mining, high-performance computing (HPC), supercomputing, large language model (LLM) training, machine learning (ML), artificial intelligence (AI), neural networks, and global climate modeling. HEDC systems prioritize raw compute power utilizing specialized hardware configurations of high-performance Graphics Processing Units (GPU), Tensor Processing Units (TPU), Central Processing Units (CPU), Field Programmable Gate Arrays (FPGA), and Application Specific Integrated Circuits (ASIC) optimized to accelerate the HEDC's specific computational task to the detriment of general-purpose computing. Since information technology (IT) operations are crucial for business continuity, a data center will generally include redundant or backup components and infrastructure for power supply, data communication connections, environmental controls (e.g., air conditioning, fire suppression), and various security devices. A large data center is an industrial-scale operation using as much electricity as a small town.

HEDC systems may be designed to operate with a heat transfer medium and system that transfers waste heat generated by an LTHE subsystem powered HEDC subsystem into the working fluid used in the thermodynamic cycle of the LTHE subsystem by means of a heat exchange power plant constituting a combined singular closed loop system requiring no external electrical connection. The heat transfer medium used in the HEDC subsystem of this disclosure may be a gas, liquid, or a 2-phase system of single or multicomponent composition depending on the optimal temperature and pressure for the HEDC application. The working fluid of the LTHE used in this disclosure may be one single component stream or multiple different compositional multicomponent streams. The present disclosure in some cases relates to a system for low initial temperature heat sources in small to large power plants combining a LTHE subsystem, including at least one turbine adapted to convert a portion of the thermal energy contained in at least one partially or fully vaporized stream into work, with a HEDC subsystem, including a heat transfer medium and transfer system, that is powered by the LTHE subsystem and is adapted to transfer the waste heat produced by the electrical devices used in the HEDC subsystem into the LTHE subsystem.

HEDC systems may be used to carry out blockchain database system processes, such as cryptocurrency processes (mining). A cryptocurrency (or crypto currency) is a digital asset designed to work as a medium of exchange that uses strong cryptography to secure financial transactions, control the creation of additional units, and verify the transfer of assets. Cryptocurrencies use decentralized control as opposed to centralized digital currency and central banking systems. The decentralized control of each cryptocurrency works through distributed ledger technology, typically a blockchain that serves as a public financial transaction database.

A blockchain is a form of database, which may be saved as a distributed ledger in a network of nodes that maintains a continuously growing list of records called blocks. Each block contains a timestamp and a link to a previous block. The data in a block cannot be altered retrospectively without significant computational effort and majority consensus of the network. Through the use of a peer-to-peer network and a distributed timestamping server, a blockchain database is managed autonomously. The administration of Bitcoin currency is currently the primary use for blockchain technology, but there are other use cases for blockchain technology to maintain accurate, tamper-proof databases. Examples include maintaining records of land titles and historical events. While the potential in blockchain technology is vast, Bitcoin remains the most widely used today.

By design, blockchains are inherently resistant (and assumed to be effectively impervious) to modification of the data-once recorded, the data in a block cannot be altered retroactively without network consensus. Blockchains are an open, distributed ledger that can record transactions between two parties efficiently and in a verifiable and permanent way. The ledger itself can also be programmed to trigger transactions automatically. Blockchains are secure by design and an example of a distributed computing system with high byzantine fault tolerance. Decentralized consensus can therefore be achieved with a blockchain. This makes the blockchain model suitable for the recording of events, medical records, and other records management activities, identity management, transaction processing and proving provenance. This offers the potential of mass disintermediation and vast repercussions for how global trade is conducted.

A blockchain facilitates secure online transactions. A blockchain is a decentralized digital ledger that records transactions on thousands of computers globally in such a way that the registered transactions cannot be altered retrospectively. This allows the participants to verify and audit transactions in an inexpensive manner. Transactions are authenticated by mass collaboration powered by collective self-interests. The result is a robust workflow where participants' uncertainty regarding data security is marginal. The use of a blockchain removes the characteristic of infinite reproducibility from a digital asset. It confirms that each unit of digital cash was spent only once, solving the long-standing problem of double spending. Blockchains have been described as a value-exchange protocol. This exchange of value can be completed more quickly, more safely and more cheaply with a blockchain. A blockchain can assign title rights because it provides a record that compels offer and acceptance. From the technical point of view a blockchain is a hash chain inside another hash chain.

A blockchain database may comprise two kinds of records: transactions and blocks. Blocks may hold batches of valid transactions that are hashed and encoded into a Merkle tree. Each block may include the hash of the prior block in the blockchain, linking the two. Variants of this format were used previously, for example in Git, and may not by itself be sufficient to qualify as a blockchain. The linked blocks form a chain. This iterative process confirms the integrity of the previous block, all the way back to the original genesis block. Some blockchains create a new block as frequently as every five or fewer seconds. As blockchains age they are said to grow in height. Blocks are structured by division into layers.

Sometimes separate blocks may be validated concurrently, creating a temporary fork. In addition to a secure hash-based history, each blockchain has a specified algorithm for scoring different versions of the history so that one with a higher value can be selected over others. Blocks that are not selected for inclusion in the chain are called orphan blocks. Peers supporting the database don't have exactly the same version of the history at all times, rather they keep the highest scoring version of the database that they currently know of. Whenever a peer receives a higher scoring version (usually the old version with a single new block added) they extend or overwrite their own database and retransmit the improvement to their peers. There is never an absolute guarantee that any particular entry will remain in the best version of the history forever, but because blockchains are typically built to add the score of new blocks onto old blocks and there are incentives to only work on extending with new blocks rather than overwriting old blocks, the probability of an entry becoming superseded goes down exponentially as more blocks are built on top of it, eventually becoming very low. For example, in a blockchain using the proof-of-work system, the chain with the most cumulative proof-of-work is always considered the valid one by the network. In practice there are a number of methods that can demonstrate a sufficient level of computation. Within a blockchain the computation is carried out redundantly rather than in the traditional segregated and parallel manner.

Maintaining a blockchain database is referred to as mining, which refers to the distributed computational review process performed on each block of data in a block-chain. This allows for achievement of consensus in an environment where neither party knows or trusts each other. Those engaged in Bitcoin mining are rewarded for their effort with newly created Bitcoins and transaction fees, which may be transferred to a digital wallet of a user upon completion of a designated task. Bitcoin miners may be located anywhere globally and may be operated by anyone. The mining hardware is tied to the blockchain network via an internet connection. Thus, little infrastructure is needed to operate and contribute to the system. All that is required to become a Bitcoin miner is the appropriate computer hardware, an internet connection and low-cost electricity. The cheaper the electricity the more reward the miner will receive relative to competition, other miners.

Mining includes the process of adding transaction records to Bitcoin's public ledger of past transactions. This ledger of past transactions is referred to as the blockchain as it is essentially a chain of blocks. The blockchain serves to confirm transactions to the rest of the network as having taken place. Bitcoin nodes use the blockchain to distinguish legitimate Bitcoin transactions from attempts to re-spend coins that have already been spent elsewhere. Mining may be intentionally designed to be resource-intensive and difficult so that the number of blocks found each day by miners remains steady. Individual blocks may be required to contain a proof-of-work to be considered valid. This proof-of-work is verified by other Bitcoin nodes each time they receive a block. Bitcoin presently uses the hash cash proof-of-work function.

One purpose of mining is to allow Bitcoin nodes to reach a secure, tamper-resistant consensus. Mining may also be the mechanism used to introduce Bitcoins into the system: Miners are paid any transaction fees as well as a subsidy of newly created coins. This both serves the purpose of disseminating new coins in a decentralized manner as well as motivating people to provide security for the system. Bitcoin mining is so called because it resembles the mining of other commodities: it requires exertion and it slowly makes new currency available at a rate that resembles the rate at which commodities like gold are mined from the ground.

Mining requires computational effort in the form of CPU cycles (CPU=central processing unit or central processor) to run a cryptographic hashing algorithm associated with the particular blockchain protocol. For a given mining processor, one can modify the computational effort through changing the core voltage or the clock rate of the processor. Doing so may result in more or less power consumed by the mining processor, and in some embodiments within this document such changes are described as changing the mining activity, or hash rate.

As the total network computational effort (or hash rate) increases on a blockchain over time, the probability for an individual miner to find a block and receive a reward diminishes. Today the Bitcoin network is so large that most individuals engaged in mining Bitcoin typically mine in pools using protocols such as the Stratum Mining Protocol. Pooling resources allows individual miners to increase their reward frequency as a trade-off for splitting the block reward with the rest of the pool. Miners who are pool mining do not need the associated equipment needed to run a mining node as they only need compute and submit proof-of-work shares issued by the mining pool.

Since the energy cost of running blockchain mining or other HEDC equipment is its primary operating cost, a trend towards mining on low-cost hydroelectric power has become prevalent. This trend has promoted the centralization of blockchain miners in specific countries with abundant hydroelectric power, as miners who do not have access to cheap hydroelectricity cannot mine profitably because they are competing with the miners who do have access. Bitcoin mining centralization has been occurring in places where there is abundant low-cost hydroelectric power. Centralization in blockchain mining is undesirable because the premise behind the blockchain innovation is not to have to trust a third party and to have inherent confidence and security through a decentralized, distributed network. Thus, there exists a need to further decentralize Bitcoin and other blockchain mining through a more decentralized source of low-cost power.

Mining is primarily a record-keeping service done through the use of computer processing power. Miners keep the blockchain consistent, complete, and unalterable by repeatedly grouping newly broadcast transactions into a block, which is then broadcast to the network and verified by recipient nodes. Presently, each block contains a SHA-256 cryptographic hash of the previous block, thus linking it to the previous block and giving the blockchain its name. To be accepted by the rest of the network, a new block must contain a proof-of-work (PoW). The PoW requires miners to find a number called a nonce (a number used just once), such that when the block content is hashed along with the nonce, the result is numerically smaller than the network's difficulty target. This PoW is easy for any node in the network to verify, but extremely time-consuming to generate. Miners must try many different nonce values (usually the sequence of tested values is the ascending natural numbers: 0, 1, 2, 3, . . . ) before a result happens to be less than the difficulty target. Because the difficulty target is extremely small compared to a typical SHA-256 hash, block hashes have many leading zeros as can be seen in this example block hash: 0000000000000000000590fc0f3eba193a278534220b2b37e9849e1a770ca959. By adjusting this difficulty target, the amount of work needed to generate a block can be changed. Every 2,016 blocks (presently approximately 14 days given roughly 10 minutes per block), nodes deterministically adjust the difficulty target based on the recent rate of block generation, with the aim of keeping the average time between new blocks at ten minutes. In this way the system automatically adapts to the total amount of mining power on the network. As of April 2022, it takes on average 122 sextillion (122 thousand billion billion) attempts to generate a block hash smaller than the difficulty target. Computations of this magnitude are extremely expensive and utilize specialized hardware.

The proof-of-work system, alongside the chaining of blocks, makes modifications to the blockchain extremely hard, as an attacker must modify all subsequent blocks in order for the modifications of one block to be accepted. As new blocks are being generated continuously, the difficulty of modifying an old block increases as time passes and the number of subsequent blocks (also called confirmations of the given block) increases.

The vast majority of mining power is grouped together in mining pools to reduce variance in miner income. Independent miners may have to work for several years to mine a single block of transactions and receive payment. In a mining pool, all participating miners get paid every time any participant generates a block. This payment is proportionate to the amount of work an individual miner contributed to the pool. Decentralized cryptocurrency is produced by the entire cryptocurrency system collectively, at a rate which is defined when the system is created and which is publicly known. In centralized banking and economic systems such as the US Federal Reserve System, corporate boards or governments control the supply of currency. In the case of decentralized cryptocurrency, companies or governments cannot produce new units, and have not so far provided backing for other firms, banks or corporate entities which hold asset value measured in it. The underlying technical system upon which decentralized cryptocurrencies are based was created by the group or individual known as Satoshi Nakamoto. As of May 2018, over 1,800 cryptocurrency specifications existed. Within a proof-of-work cryptocurrency system such as Bitcoin, the safety, integrity and balance of ledgers is maintained by a community of mutually distrustful parties referred to as miners: who use their computers to help validate and timestamp transactions, adding them to the ledger in accordance with a particular timestamping scheme. In a proof-of-stake (POS) blockchain, transactions are validated by holders of the associated cryptocurrency, sometimes grouped together in stake pools. Most cryptocurrencies are designed to gradually decrease the production of that currency, placing a cap on the total amount of that currency that will ever be in circulation. Compared with ordinary currencies held by financial institutions or kept as cash on hand, cryptocurrencies can be more difficult for seizure by law enforcement.

Referring to FIG. 3, an example of a self-contained high-energy-density computing system, such as a self-contained HEDC system 10, is illustrated. The system 10 may comprise a low temperature heat engine (LTHE) 12, a heat exchanger 16, and high-energy-density computing (HEDC) device 22, such as a blockchain mining device. One or both a coolant loop 24 and working fluid loop 26 may be present, for example formed by piping. The LTHE 12 may have the working fluid loop 26 extended between a heat source and a heat sink, such as a heat source heat exchanger 27 and a heat sink heat exchanger 28. The heat exchanger 16 may on the working fluid loop 26. The HEDC device 22 may be connected to receive electricity generated from the LTHE 12, for example via power cables 40. The coolant loop 24 may be extended between the HEDC device 22 and the working fluid loop 26, for example between device 22 and heat exchanger 16. During use, electricity may be generated using the low temperature heat engine (LTHE) 12. The HEDC device 22 may be operated using electricity generated from the LTHE 12, for example to carry out blockchain mining processes. The HEDC device may be simultaneously cooled, for example by heat exchange with working fluid of the LTHE 12.

Ocean Thermal Energy Conversion (OTEC) is a relatively obscure example of a power-generation process that incorporates an LTHE. OTEC uses the ocean thermal gradient between cooler deep and warmer shallow or surface seawaters to run a heat engine and produce useful work, usually in the form of electricity. OTEC can operate with a very high-capacity factor and so can operate in base load mode. The denser cold-water masses, formed by ocean surface water interaction with cold atmosphere in quite specific areas of the North Atlantic and the Southern Ocean, sink into the deep-sea basins and spread in entire deep ocean by the thermohaline circulation. Upwelling of cold water from the deep ocean is replenished by the downwelling of cold surface sea water. Among ocean energy sources, OTEC is one of the continuously available renewable energy resources that could contribute to base-load power supply. The resource potential for OTEC is considered to be much larger than for other ocean energy forms. Some experts believe that up to 88,000 TWh/yr. of power could be generated from OTEC without affecting the ocean's thermal structure. OTEC systems may be either closed-cycle or open-cycle. Closed-cycle OTEC may use working fluids that are typically thought of as refrigerants such as ammonia or R-134a. These fluids have low boiling points, and are therefore suitable for powering the system's generator to generate electricity. The most commonly used heat cycle for OTEC to date is the Rankine cycle, using a low-pressure turbine. Open-cycle engines use vapor from the seawater itself as the working fluid.

Referring to FIGS. 1-3, the LTHE 12 may carry out a suitable energy conversion process, such as an ocean thermal energy conversion (OTEC) process. In FIG. 1, two types of OTEC power plant facilities are shown—an on-shore facility 46 and an off-shore facility 48. The HEDC system 22 may form part of facility 46 or 48 to collocate the HEDC device 22 and the LTHE 12. Colocation may be achieved by situating the device 22, for example a containerized blockchain mining rig, adjacent or in close proximity with the LTHE 12, for example within zero to 500 meters of each other, although distances longer than 500 meters may be used. In the example shown, an onshore facility 46 may include a power plant 49 and an HEDC building 56, located adjacent to a body of water such as the ocean. In an off-shore example, the facility 48 may form a boat 47, for example a barge as shown, supporting power plant 49 and the HEDC, for example building 56. Building 56 may house a HEDC device 22, which may be connected to exchange heat and/or receive power from power plant 49 via appropriate connections 58 such as cabling or piping. In both on and offshore examples, OTEC power plant 49 may receive cold water from a cold-water piping 50, whose input may be located below a surface 76 of the ocean or other body of water in which the OTEC process is carried out, for example at or near the floor 74 of the ocean or sea. As well, the OTEC power plant 49 may receive warm water from warm water piping 52, whose input may be located at or near a surface 76 of the ocean. Mixed temperature piping 54 may also be used as an input or output of such water.

Referring to FIGS. 1 and 2, as mentioned the off-shore example of an OTEC facility 48 may involve the use of a boat 47. One or both of the HEDC device 22 (represented by building 56) and the OTEC power plant 49 may be located on the boat 47, which may be one or more boats. In some cases, the power plant 49 and device 22 are on separate boats, or one or the other is located on-shore. The off-shore embodiments of the present system 10 may be used to carry out the disclosed methods while the boat 47 is floating in the ocean. In one example, which may be referred to as “grazing”, the methods may be carried out while the boat 47 is moving. The ability to relocate the facility 48 may be beneficial to assist a user to select an optimal or suitable location of water over which to carry out power generation and HEDC operations. In the example shown, various techniques may be used to assist the operation of the system 10, for example, piping, such as piping 52 or 54 may depend directly from the boat 47. Piping 50 may also depend from the boat 47, but may incorporate various parts to stabilize and support the piping 50. A transfer pipe 60 may be supported by both boat 47 and a pipe pendant 62, which may connect to a float 78 on the surface 76 of the ocean. The use of a float 78 system may be used to help target the piping 50. Various weights, such as weights 66, and 72, and cabling or other mooring lines 68, 72 and 80 may be used to anchor the piping 50 where desired—in the example shown, on the ocean floor 74.

Referring to FIG. 3, an example of a self-contained HEDC system 10 is disclosed. One or more circulation pumps 38 and 18 may be present on the coolant loop or working fluid loop, respectively, to drive fluid around each respective loop. The example shown involves closed loop coolant and working fluid circuits. In the working fluid loop 26 of LTHE 12, working fluid, such as ammonia, circulates between hot and cold regions of the loop.

Referring to FIG. 3, the LTHE 12 may comprise a turbomachine, such as a turbine 14, connected to generate electricity for the HEDC device 22. Turbomachinery, in mechanical engineering, may describe machines that transfer energy between a rotor and a fluid, including both turbines and compressors. A turbine is a rotary mechanical device that extracts energy from a fluid flow and converts it into useful work. The work produced can be used for generating electrical power when combined with a generator. A turbine is a turbomachine with at least one moving part called a rotor assembly, which is a shaft or drum with blades attached. Moving fluid acts on the blades so that they move and impart rotational energy to the rotor.

Referring to FIG. 3, the operation of the LTHE 12 may proceed as follows in the example shown. Relatively cold working fluid, such as liquefied working fluid, may enter heat source heat exchanger 27 via piping 26E. In exchanger 27, the working fluid may be heated, for example gasified, using heat from warm water entering the exchanger 27 via piping 30, with the warm water thereafter exiting exchanger 27 via piping 32. The warm working fluid may then travel via piping 26A into heat exchanger 16, which is connected downstream of the heat source heat exchanger 27 and upstream of the turbomachine 14. The working fluid may be warmed again within heat exchanger 16, and thereafter passed via piping 26B into turbine 14, where the working fluid performs work to generate electricity. Upon exiting turbine 14, the working fluid may travel via piping 26C into a heat sink heat exchanger 28, where the working fluid is cooled, and in some cases liquefied, by heat exchange with relatively cold water from piping 34 (which may thereafter leave the exchanger 28 via piping 36. The now cold working fluid may travel via piping 28D, and may be conveyed at any point in the process via a circulation pump 18. Cold working fluid may travel via piping 28E back into exchanger 27 to repeat the electricity generation process.

Referring to FIG. 3, the HEDC device or devices 22 may operate and be cooled synergistically with the LTHE 12 process. As mentioned, the operation of the turbine 14 may generate electricity, which may be supplied to power the device 22 via cables 40. The operation of the device 22 may generate heat, particularly where energy-intensive HEDC processes are being carried out by device 22. A coolant loop 24 may convey a coolant, such as water, about a circuit to cool the device 22. In the example shown, a closed loop 24 is shown, but other cases may incorporate an open loop coolant system for device 22. In the example shown, warm coolant leaves the device 22 via piping 24A, and may at any suitable point in the loop 24 be conveyed by a circulation pump 38. The coolant travels via piping 24B into heat exchanger 16, where heat is exchanged from the coolant and supplied to the working fluid travelling in loop 26. After having lost heat and reduced temperature in exchanger 16 due to heat transfer to the working fluid, the relatively cool coolant then travels back to the device 22 via piping 24C, where the coolant receives heat and increases in temperature by heat exchange with the device 22, cooling the device 22 in turn.

Referring to FIG. 3, in some cases the coolant is used to superheat the working fluid via heat exchange. For example, working fluid travelling in pipe 26A may be travelling in a state at or below a boiling point of the working fluid. Such fluid may enter exchanger 16 and may be superheated by heat exchange with coolant. In thermodynamics, superheating (sometimes referred to as boiling retardation, or boiling delay) is the phenomenon in which a liquid is heated to a temperature higher than its boiling point, without boiling. This is a so-called metastable state or meta state, where boiling might occur at any time, induced by external or internal effects. The heat exchanger and the coolant loop may thus be structured to superheat working fluid in the working fluid loop. The superheating of the working fluid may enhance the operation of the downstream turbine 14, as the turbine permits rapid expansion of the working fluid to carry out work to generate electricity.

Referring to FIGS. 9 and 10, an HEDC device 22 may incorporate various suitable parts and connections. Referring to FIG. 10, the HEDC device 22 may comprise a plurality of processors 100 connected to a network interface 124, such as a satellite unit or other part suitable for connecting to a remote network. The network interface 124 may be connected to receive and transmit data, for example through the internet, to a peer-to-peer network that stores or has access to a blockchain database. A blockchain database is a distributed database stored on plural nodes in the peer-to-peer network, and that stores transactional information for a digital currency. The blockchain database is understood to be operated by third parties, typically nodes or mining pools, and during operation, a user carrying out the method will use the interface 124 to connect with and receiving instructions/send proof of work to, the database, node, or mining pool. The processors 100 may be connected to the network interface 124 and adapted to mine transactions associated with the blockchain database and to communicate with the blockchain database.

Referring to FIG. 9, a HEDC device 22, for example one tailored for Bitcoin mining, machine learning, or supercomputing, may incorporate one or more processors 100 with an application-specific integrated circuit (ASIC) chip, field-programmable gate arrays (FPGA) graphics processing units (GPUs), or tensor processing units (TPUs). An ASIC may be an integrated circuit (IC) chip customized for a particular use, rather than intended for general-purpose use. For example, a chip designed to run in a digital voice recorder or a high-efficiency bitcoin miner is an ASIC. Application-specific standard product (ASSP) chips may be intermediate between ASICs and industry standard integrated circuits like the 7400 series or the 4000 series. ASIC chips may be typically fabricated using metal-oxide-semiconductor (MOS) technology, as MOS integrated circuit chips. As feature sizes have shrunk and design tools improved over the years, the maximum complexity (and hence functionality) possible in an ASIC has grown from 5,000 logic gates to over 100 million. Modern ASICs often include entire microprocessors, memory blocks including ROM, RAM, EEPROM, flash memory and other large building blocks. Such an ASIC is often termed a SoC (system-on-chip). Designers of digital ASICs often use a hardware description language (HDL), such as Verilog or VHDL, to describe the functionality of ASICs. Field-programmable gate arrays (FPGA) are the modern-day technology for building a breadboard or prototype from standard parts; programmable logic blocks and programmable interconnects allow the same FPGA to be used in many different applications. For smaller designs or lower production volumes, FPGAs may be more cost-effective than an ASIC design, even in production. The non-recurring engineering (NRE) cost of an ASIC can run into the millions of dollars. Therefore, device manufacturers typically prefer FPGAs for prototyping and devices with low production volume and ASICs for very large production volumes where NRE costs can be amortized across many devices. One or more ASIC chips may be contained on each processor, for example located in single or plural arrays or groups in one or more hash boards. TPUs (Tensor Processing Units) are AI accelerator chips designed specifically for machine learning workloads. They are application-specific integrated circuits (ASICs) built from the ground up to efficiently execute machine learning models, especially for inference in applications like image recognition, speech recognition, and language understanding. TPUs excel at performing the tensor calculations that are fundamental to deep neural networks. Their architecture is optimized for low-precision arithmetic operations used in deep learning, enabling very high computational throughput while being more power and space efficient than general-purpose processors like CPUs or GPUs for these workloads. GPUs (Graphics Processing Units) are specialized processors originally designed for rendering graphics and image processing. However, their highly parallel architecture made them well-suited for various compute-intensive workloads like machine learning, deep learning, scientific simulations, financial modeling, and computational biology. GPUs contain thousands of smaller, more efficient cores designed to handle multiple tasks simultaneously, as opposed to CPUs with fewer, more powerful cores. This parallel processing capability allows GPUs to accelerate applications that can be parallelized across the GPU's many cores. GPUs require specialized programming models like CUDA or OpenCL to leverage their parallel architecture effectively.

Referring to FIG. 9, each processor 100 may have suitable characteristics. The example shown illustrates an S9i™ rig manufactured and sold in association with the ANTMINER™ brand by BITMAIN™ for the purpose of mining Bitcoin transactions. The processor 100 may incorporate one or more controllers 108. The Antminer™ S9i™'s control board (controller 108) employs the fast Dual ARM® Cortex®-A9 microprocessor with CoreSight™. The S9i's control board may use a Xilinx® Zynq®-7000 series FPGA with a Dual ARM® Cortex®-A9 microprocessor. The processor 100 may comprise a network connector 110 (for an ethernet cable), such as one that supports Gigabit Ethernet to ensure that mined blocks are submitted instantly. Each processor board 112 may be mounted on a body 102 of the processor 100, and contains one or more application-specific integrated circuit chips. Each Antminer™ S9i™ employs a plurality of ASICs, for example 189 such chips to deliver more hash rate and efficiency than any bitcoin miner ever made before it. The processor 100 may comprise a suitable body 102 upon which to mount components. In the example shown, body 102 is a high-grade aluminum case.

Referring to FIG. 9, the processor 100 may include one or more cooling mechanisms. The body 102 may include one or more heat-sinks. One or more fans may be connected to direct fluid, such as air, through a cooling fluid (coolant) passageway through the body 102, and across the ASIC processor 100, to maintain the ASIC processor 100 within a respective operating range of temperature during use. One or more temperature sensors (not shown) may be used to monitor temperature and adjust fan and/or computing operation. The fans may include an intake fan 104 at an intake end of the body 102. The fans may include a discharge fan 106 at a discharge end of the body 102. By using two computer-controlled high-speed fans 104 and 106 on both ends of a tube-shaped body 102, hot fluid is rapidly replaced by cooler fluid at the required pace. By using two computer-controlled fans to keep the processor 100 cool, the processor 100 remains efficient and powerful. The processor 100 may use a combination of conduction and convection cooling to make the miner perform best without getting hotter than any other terahash bitcoin miner. In some cases, each chip of the processor 100 may be fitted with custom-made heat sinks, for example that are made of a high-grade Aluminum alloy.

Referring to FIGS. 3 and 10, a HEDC device 22 may exchange heat with a coolant loop 24 via a suitable means. In the example shown, the device 22 may be cooled via an immersion cooling process, although other processes may be used, including air-cooled processes, or processes that exchange heat between air and liquid coolant loops. In the immersion cooling example, incoming low temperature coolant enters the device 22, via piping 24C, absorbing heat from processors 100, and exiting device 22 via piping 24A. A pump 38 may convey coolant via piping 24B into exchanger 16, where heat exchange occurs with working fluid in loop 26. The relatively lower temperature coolant than travels via piping 26C back into device 22 to repeat the process.

Referring to FIG. 10, the system 10 may be configured to maintain the processor 100 of the HEDC device 22 within a safe operating range of temperature, for example at or near room temperature. One or more controller 120 may be configured to operate one or both the LTHE 12 and coolant loop 24 and/or device 22 to maintain the safe operating range of temperature. The controller 120 may also be configured to ensure that working fluid is at an optimal or suitable temperature and pressure leaving exchanger 16 for operation in turbine 14. Various systems may be incorporated to permit adjustment of outgoing temperatures of working and coolant fluids to optimize operation. One or more temperature and/or pressure sensors 122 may be used to monitor properties of fluid and adjust operation as needed.

Referring to FIG. 4, an example similar to the embodiment of FIG. 3 is illustrated. The primary difference is that in FIG. 4, no pump 38 is provided. In the example shown, the heat transfer medium employed by the HEDC application (device 22) may allow for the removal of the pump.

Referring to FIG. 5, the system 10 may operate using a plurality of turbomachines, for example turbines 14A and 14B. The plurality of turbomachines may comprise a first turbomachine (turbine 14A) downstream of the heat source (exchanger 27) but upstream of the heat exchanger 16. The turbomachines may comprise a second turbomachine (turbine 14B) downstream of the heat exchanger 16 but upstream of the heat sink (exchanger 28). In the example shown, an LTHE 12 incorporates a single stream or dual streams that are reheated by waste heat transferred from the HEDC (device 12) operation by means of a heat exchange apparatus and a dual turbine system providing power to the HEDC operation. The working fluid may be cycled between the first turbine 14A downstream of the heat source but upstream of the heat exchanger 16, the second turbine 14B downstream of the heat exchanger 16 but upstream of the heat sink. As the heated working fluid exits exchanger 27, it travels via piping 26A-1 to turbine 14A, where work is performed to generate electricity that may be provided to device 22 via power cables 40A. After turbine 14A, working fluid may travel via piping 26A-2 to exchanger 16, where the working fluid is heated again, but by coolant in loop 24. The heated working fluid then travels via piping 26B into second turbine 14B. Turbine 14B then generates electricity and provides same to device 22 via cables 40B.

Referring to FIG. 6, a variation of the embodiment of FIG. 5 is shown, except with turbine 14A recycling working fluid back into exchanger 27. The working fluid loop 26 may be structured to cycle working fluid, in series, from the heat source heat exchanger 27, into the first turbomachine 14A, back into the heat source heat exchanger, and into the second turbomachine. The working fluid loop 26 may be cycled in series, from a heat source heat exchanger 27, into the first turbomachine (turbine 14A), back into the heat source heat exchanger 27, and into the second turbomachine (turbine 14B). Thus, in the example shown, warmed working fluid exits exchanger 27 and travels via piping 26A-1 into turbine 14A. Turbine 14A then generates electricity, which is provided by cables 40A to device 22. The outgoing working fluid then travels by piping 26A-2 backing exchanger 27, where the working fluid receives additional heat from the heat source. The warmed working fluid then travels via piping 26A-3 into exchanger 16. The embodiment demonstrates a single stream or dual streams reheated by a dual flow heat exchanger in a regenerative Rankine cycle, then superheated by waste heat transferred from the HEDC operation by means of a heat exchange apparatus and a dual turbine system providing power to the HEDC operation.

Referring to FIG. 7, an embodiment is illustrated similar to that of FIG. 3, except that the coolant heat exchanger 16 is positioned upstream of the heat source heat exchanger 27. In the example shown, coolant travelling through exchanger 16 warms working fluid entering via piping 26E and leaving via piping 26F, upstream of the heat source heat exchanger 27.

Referring to FIG. 8, some embodiments of the system 10 may incorporate a gas-liquid separator 42. A gas-liquid separator 42 may be provided on the working fluid loop 26, for example downstream of the heat source (exchanger 27) and upstream of the turbomachine (turbine 14). The separator 42 may be structured to separate the working fluid from piping 26A-1 into: a gasified stream that is supplied to the turbine 14, for example via piping 26A-2, and, a liquefied stream that is supplied to the heat exchanger 16, for example via piping 26A-3, and then to the turbomachine (turbine 14). The liquefied stream passing through piping 26A-3 may exchange heat with coolant via exchanger 16, and thereafter pass into a stream mixing apparatus 44 that re-combines the two streams of working fluid from piping 26A-2 and 26B-1 into one stream in piping 26B-2, which is then supplied to turbine 14.

### Efficiencies and Cost Savings

The system of the present disclosure, in any of the embodiments depicted in FIGS. 1-10 in addition to any other embodiments not depicted whereby waste heat from an HEDC computing application is transferred to a LTHE that provides it with electrical power, may provide an advantage both in cost and efficiency to both the HEDC and LTHE subsystems above either individually.

Efficiency of a simple Rankine cycle (η_therm) is defined by the following equation:

$${η}_{therm} \approx \frac{{\dot{W}}_{turb}}{{\dot{Q}}_{i n}}$$

Where \dot{Q}ᵢₙ is the heat flow rate to the system and \dot{W}_{turb} is the power produced by the turbine. In any embodiment of the present disclosure in which the waste heat is used to super heat the working fluid, as depicted in FIGS. 3, 4 and 6, it is evident that for given pressures, superheating the steam increases the Rankine-cycle efficiency by increasing the \dot{W}_turb that can be extracted from the system. Further, it is evident from first principles that by reincorporating the net output from a heat engine, be it a preheat, reheat, regenerative, or super heating based cycle, back into itself one reduces \dot{Q}ᵢₙ thereby increasing ηₜₕₑᵣₘ.

The efficiency of a data center in general is generalized to the following formula for Power usage effectiveness (PUE) where:

$$PUE = \frac{Total Facility Energy}{IT Equipment Energy}$$

Where IT Equipment Energy only includes energy used to power computing devices and where Total Facility Energy also includes the IT Equipment in addition energy consumed by everything else in the data center (e.g. lighting, cooling, etc.). Through the colocation and direct integration of a HEDC data center within a LTHE based power plant every component of the data center sans computing devices and cooling falls under the parasitic load category of the power plant rather than the IT Facility. The cooling energy for the IT equipment, which in a. normal data center can consume a significant percentage of the IT Equipment energy, can be reduced to theoretically zero, via choice of heat transfer medium, and use of the LTHE itself as the heat sink. While the ideal data center PUE of zero has been demonstrated in the past over a limited duration, the disclosure presented here can sustain it over extended periods.

Cost savings can be achieved in both the LTHE and HEDC subsystems through the integration presented in this disclosure through a number of mechanisms. By combining the HEDC heat removal equipment with the Rankine cycle, either by preheat, reheat, regenerative, or superheating mechanisms, one reduces the equipment needed and thereby cost. In any embodiment of this disclosure in which the waste heat from the HEDC is used to increase the vapor quality of the working fluid entering a turbine of the LTHE, thereby reducing damage to the turbine blades from pitting and other effects of condensation during expansion. By this method the life of a turbine can be extended beyond a LTHE without this disclosure, reducing costs over the lifetime of the power plant and by decreasing downtime needed for repairs.

Finally, cost savings are achieved through power distribution. Exporting power from a power plant to the grid has a number of inefficiencies and losses inherent to it from controls on the turbine for precise frequency regulation. By coupling a LTHE directly with a HEDC application one obviates the need for the expensive equipment required for grid tie in and increases the efficiency of the turbine from elimination of the need to regulate frequency. On the HEDC side, power distribution in a data center from grid tie into IT equipment requires numerous conversion steps and expensive infrastructure. By eliminating the grid tie in and with the flexibility to produce power in the manner best suited for the particular IT equipment in use, the power distribution equipment can be greatly simplified eliminating costly equipment and conversion losses.

In summary, integrating an LTHE with HEDC as presented in this disclosure allows for the construction of both the most efficient data center and LTHE.

In some of the embodiments, a HEDC device 22, for example a blockchain mining device, may be provided within a portable building. A portable building may have walls, a base, and a roof, and racking for processors. One example of a suitable building includes an intermodal transport container-a large standardized shipping container, designed and built for intermodal freight transport, meaning these containers can be used across different modes of transport—from ship to rail to truck—without unloading and reloading their cargo. Intermodal containers are primarily used to store and transport materials and products efficiently and securely in the global containerized intermodal freight transport system, but smaller numbers are in regional use as well. These containers are known under a number of names, such as simply container, cargo or freight container, ISO container, shipping, sea or ocean container, sea van or (Conex) box, sea can, or C can. Transport containers may be transferred between rail, truck, and ship by container cranes at container terminals. Forklifts, reach stackers, straddle carriers, and cranes may be used to load and unload trucks or trains outside of container terminals. Swap bodies, side lifters, tilt deck trucks, and hook trucks may allow transfer to and from trucks with no extra equipment. ISO-standard containers can be handled and lifted in a variety of ways by their corner fixtures, but the structure and strength of forty five-foot (type E) containers limits their tolerance of side-lifting, nor can they be forklifted, based on ISO 3874 (1997).

Blockchains may be used in association with non-currency applications, such as in the case of a non-fungible token (NFT), which is a unique and non-interchangeable unit of data stored on a digital ledger (blockchain). NFTs may be associated with easily reproducible items such as photos, videos, audio, and other types of digital files as unique items (analogous to a certificate of authenticity). NFTs use blockchain technology to provide a public proof of ownership. Copies of the original file are not restricted to the owner of the NFT, and can be copied and shared like any file. The lack of interchangeability (fungibility) distinguishes NFTs from traditional blockchain cryptocurrencies, such as Bitcoin. The embodiments of this disclosure cover blockchain engaging systems, including those that relate to cryptocurrencies, NFTs, and others.

In the claims, the word “comprising” is used in its inclusive sense and does not exclude other elements being present. The indefinite articles “a” and “an” before a claim feature do not exclude more than one of the feature being present. Each one of the individual features described here may be used in one or more embodiments and is not, by virtue only of being described here, to be construed as essential to all embodiments as defined by the claims.

1. A self-contained High Energy Density Computing Data Center system comprising:
a low temperature heat engine (LTHE) with a working fluid loop extended between a heat source and a heat sink, in which the LTHE is structured to carry out an ocean thermal energy conversion (OTEC) process in use;
a high energy density computing data center (HEDC) connected to receive electricity generated from the LTHE, in which the self-contained HEDC system forms an offshore facility that collocates the HEDC device and the LTHE;
a heat exchanger on the LTHE; and
a coolant loop extended between the HEDC and the heat exchanger, such that LTHE is structured to simultaneously provide power and cooling to the HEDC forming the self-contained HEDC system.

2. The self-contained HEDC system of claim 1, wherein the HEDC comprises a task-specialized configuration of processors comprising one or more of: high-performance Graphics Processing Units (GPUs), Tensor Processing Units (TPUs), Field Programmable Gate Arrays (FPGAs), and Application Specific Integrated Circuits (ASICs), arranged and interconnected to optimize performance for specific computational tasks.

3. The self-contained HEDC system of claim 1 in which the HEDC comprises a blockchain mining device.

4. The self-contained HEDC system of claim 1 in which the HEDC is configured to carry out one or more of the following operations:
artificial intelligence, machine learning, large language models, generative AI, Neural Network, and supercomputing.

5. The self-contained HEDC system of claim 1 in which:
the LTHE comprises a turbomachine connected to generate electricity for the HEDC device; and
the heat exchanger is on the working fluid loop upstream of the turbomachine.

6. The self-contained HEDC system of claim 5 in which the turbomachine comprises:
a first turbomachine downstream of the heat source but upstream of the heat exchanger; and
a second turbomachine downstream of the heat exchanger but upstream of the heat sink.

7. The self-contained HEDC system of claim 6 in which:
a heat source heat exchanger is between the heat source and the working fluid loop; and
the working fluid loop is structured to cycle working fluid, in series, from the heat source heat exchanger, into the first turbomachine, back into the heat source heat exchanger, and into the second turbomachine.

8. The self-contained HEDC system of claim 1 further comprising a gas-liquid separator on the working fluid loop downstream of the heat source and upstream of the turbomachine, and structured to separate the working fluid into:
a gasified stream that is supplied to the turbomachine; and
a liquefied stream that is supplied to the heat exchanger and then to the turbomachine.

9. The self-contained HEDC system of claim 1 in which the heat exchanger and the coolant loop are structured to superheat working fluid in the working fluid loop.

10. The self-contained HEDC system of claim 1 further comprising a controller configured to operate the LTHE and coolant loop to maintain a processor of the HEDC device within a safe operating range of temperature.

11. The self-contained HEDC system of claim 1 further comprising:
a heat source heat exchanger between the heat source and the working fluid loop; and
a heat sink heat exchanger between the heat sink and the working fluid loop.

12-14. (canceled)

15. The self-contained HEDC system of claim 1 in which:
the HEDC device comprises a plurality of processors connected to a network interface;
the network interface is connected to receive and transmit data through the internet.

16. The self-contained HEDC system of claim 15 in which:
the HEDC comprises a blockchain mining device;
the network interface is connected to a peer-to-peer network that stores or has access to a blockchain database, which is a distributed database stored on plural nodes in the peer-to-peer network, and stores transactional information for a digital currency; and
the processors are connected to the network interface and adapted to mine transactions associated with the blockchain database and to communicate with the blockchain database.

17. A method comprising operating the HEDC device of the self-contained HEDC system of claim 1 using electricity generated from the LTHE.

18. A method comprising:
generating electricity using a low temperature heat engine (LTHE) that carries out an ocean thermal energy conversion (OTEC) process;
operating an HEDC device, using electricity generated by the LTHE; and
cooling the HEDC device by heat exchange with the LTHE; and
in which the method is carried out on an off-shore facility.

19. The method of claim 18 in which generating electricity comprises cycling working fluid around a working fluid loop of the LTHE between a heat source, a turbomachine, and a heat sink.

20. The method of claim 19 in which cooling comprises cycling coolant around a coolant loop between the HEDC device and a heat exchanger, which is on the working fluid loop upstream of the turbomachine.

21. The method of claim 20 in which:
the turbomachine comprises a first turbomachine and a second turbomachine; and
the working fluid is cycled between:
the first turbomachine downstream of the heat source but upstream of the heat exchanger; and
the second turbomachine downstream of the heat exchanger but upstream of the heat sink.

22. The method of claim 18 in which cycling the working fluid comprises:
cycling the working fluid from the heat source into a gas-liquid separator on the working fluid loop downstream of the heat source and upstream of the turbomachine; and
separating the working fluid, using the gas-liquid separator into:
a gasified stream that is supplied to the turbomachine; and
a liquefied stream that is supplied to the heat exchanger and then to the turbomachine.

23. The method of claim 18 in which heat exchange with the working fluid superheats working fluid in the working fluid loop.

24. The method of claim 18 in which cooling comprises maintaining a processor of the HEDC device within a safe operating range of temperature.

25-26. (canceled)

27. The method of claim 25 further comprising adjusting an input power of the HEDC device to balance other loads powered by the LTHE.

28. The self-contained HEDC system of claim 1 in which the heat exchanger is on the working fluid loop.
